(19) United States
(12) Patent Application Publication
(10) Pub. No.: US 2023/0235801 A1
(43) Pub. Date: Jul. 27, 2023

(54) FORCE SENSING DEVICE, VEHICLE BRAKING DEVICE INCORPORATING SUCH A FORCE SENSING DEVICE, AND METHOD OF PRODUCTION THEREOF

(71) Applicant: ITT ITALIA S.R.L., Lainate (IT)

(72) Inventors: Stefano SERRA, San Pietro Val Lemina (Torino) (IT); Umberto VIGNOLO, Barge (CN) (IT); Marco TERRANOVA, Torino (IT)

(21) Appl. No.: 18/007,981

(22) PCT Filed: May 21, 2021
(86) PCT No.: PCT/EP2021/063634

§ 371 Date: Dec. 2, 2022

(30) Foreign Application Priority Data
Jun. 5, 2020 (IT) 102020000013423

(51) Int. Cl. F16D 65/092; F16D 66/02; G01L 1/16; H10N 30/30; H10N 30/87; H10N 30/06; H10N 30/045

(52) U.S. Cl. CPC F16D 65/092; F16D 66/027; G01L 1/16; H10N 30/302; H10N 30/87; H10N 30/06; H10N 30/045; F16D 2066/005

(57) ABSTRACT

The force sensing device (1) comprising: a sheet (2) of piezoelectric; at least a first and a second interdigitated electrodes (5, 50) located on a first main face (3) and at least a third and fourth interdigitated electrodes (6, 60) located on a second main face (4) of the sheet (2), the first and third electrodes (5, 6) being aligned to each other along a normal stress direction (N), the second and fourth electrodes (50, 60) being aligned to each other along the normal stress direction (N); the piezoelectric material comprising first portions (100) facing the first and third electrodes (5, 6) interposed with second portions (101) facing the second and fourth electrodes (50, 60), the first portions (100) having bulk electric polarization with vector field (E) mostly oriented in alignment with the normal stress direction (N), the second portions (101) having bulk electric polarization with vector field (E) mostly oriented transversally to the normal stress direction (N).

### FIELD

The following disclosure relates to a force sensing device, a vehicle smart brake pad comprising a force sensing device, and a production process thereof.

### SUMMARY

Piezoelectricity is the electric charge that accumulates inside a particular type of solid materials in response to external applied mechanical stress.

Piezoelectric materials include nanocrystals of quartz, tourmaline and Rochelle salt, but they show a relatively small piezoelectric response to external solicitations.

To overcome this problem some polycrystalline ferroelectric ceramics are synthesized, such as barium titanate (BaTiO3) and lead zirconate titanate (PZT) such that the synthesized ceramics exhibit larger displacements or induce larger electric voltages after mechanical stress is applied.

In order to use these synthesized piezoelectric materials properly, a polarization procedure is performed. For this purpose, a strong electric field of several kV/mm is applied to create an asymmetry in the previously unorganized ceramic compound. The electric field causes a reorientation of the spontaneous polarization and at the same time, domains with a favorable orientation to the polarity field direction grow while those with an unfavorable orientation are suppressed. After polarization, most of the reorientations are preserved even without the application of an electric field.

Piezoceramic compounds are produced in several different ways. Manufacturing techniques may be based on the mechanical hydraulic pressing of spray-dried granular material. After production, the compound is sintered at temperatures of up to approx. 1300° C. The result is a solid ceramic material having high density. Later, the piezoelectric material is polarized as described above and then the sintered ceramic, which is very hard, can be sawn and machined, if required. The compacts come in different shapes as disks, plates, rods, and cylinders. The last phase of the manufacturing process comprises the deposition of electrodes. Electrodes are applied to the piezoceramic material by screen-printing technology or PVD (sputtering) and subsequently baked at temperatures above 800° C.

Current production technologies for manufacturing force sensing devices based on piezoelectrical materials involve different mechanical steps to produce the piezoelectric material, subsequent machining of the shapes and sizes of the piezoelectric material, and final coupling of the piezoelectric materials with the electrodes.

Accordingly, force sensing devices made from piezoelectrical materials according to existing manufacturing techniques are expensive and require a long production process.

Furthermore, existing force sensing devices can accurately read either shear stress or normal stress but not both with the same accuracy.

This is why existing solutions typically include dedicated shear force detection devices and dedicated normal force detection devices.

WO2019/171289 discloses interdigitated electrodes to read shear forces.

Various embodiments of the present disclosure can address one or more of the aforementioned concerns, or other concerns.

For example, according to the present disclosure, a single force sensing device can provide accurate readings of both shear stress and normal stress.

According to embodiments of the manufacturing methods and corresponding devices of the present disclosure, piezoelectric sensing devices that can measure both shear and normal stress include fewer components, can be built according to a simplified assembly process, and last but not least at a reduced overall cost.

Screen-printing technology is generally a fast and low-cost process. The screen printing of a piezo element can allow a robust design and a cost reduction in an industrial process for making a sensorized object, for instance a smart brake pad for vehicles.

Compared to the technology currently on the market for piezoelectric sensors, screen-printing reduces the production steps since the sensor itself can be produced directly on the object to be sensorized, and it can also be polarized “in situ”. That is, in contrast to manufacturing methods in which the piezoelectric material is polarized during or just after the manufacturing process of the sensor, the piezoelectric material of the present disclosure may be polarized after the sensor has been manufactured and installed into an application due to the relatively low voltage required to polarize the piezoelectric material of the present disclosure. Therefore, it is not necessary to produce the sensor, polariz it and then install it on the object but it would directly be integrated in the same. Alternatively, the piezoelectric material of the present disclosure may be polarized during the manufacturing process of the sensor itself. The screen-printing technique is widely used in printed electronics and is one of the most promising technologies to manufacture a wide range of electronic devices. The advantages of screen-printed sensors include sensitivity, selectivity, possibility of mass-production and miniaturization.

Screen-printing technology consists of depositing successive layers of special inks or pastes onto an insulating substrate. The pastes are usually based on a polymeric binder with metallic dispersions or graphite, and can also contain functional materials such as cofactors, stabilizers and mediators.

The advantage of screen-printed technology resides in the possibility for the manufacturing all the phases of the device fabrication in a single step, that is, from electrode to material deposition. Furthermore, the procedure for the in-situ polarization of the fabricated device may be very simple.

The devices fabricated using this type of technology are typically very thin (h=10÷100 μm) and do not have particular limitation in geometry or planar extension. Taking advantage of these geometrical properties is possible to define some electrodes configuration in order to control the field direction, with the aim of obtaining preferential polarization directions.

A smart brake pad is a sensorized brake pad configured (e.g., with appropriate software and hardware system architecture and some algorithms) to measure one or more parameters, such as the brake pad temperature and/or static and dynamic quantities including normal and shear forces applied during braking.

Various embodiments of the present disclosure can address one or more of the aforementioned concerns, or other concerns associated with current production technologies.

For example, some embodiments include providing a force sensing device comprising:
a sheet of piezoelectric material having a first and a second main faces parallel to each other identifying a shear stress direction and a normal stress direction orthogonal to said shear stress direction;
at least a first and a second interdigitated electrodes located on said first main face;
at least a third and fourth interdigitated electrodes located on said second main face;

wherein said first and third electrodes are normal stress reading electrodes having digits aligned along said normal stress direction;

wherein said second and fourth electrodes are shear stress reading electrodes having digits aligned along said normal direction;

wherein said piezoelectric material comprises, along said shear stress direction, first portions facing said digits of said first and third electrodes interposed with second portions facing said digits of said second and fourth electrodes, said first portions having bulk electric polarization with vector field mostly oriented in alignment with said normal stress direction, said second portions having bulk electric polarization with vector field mostly oriented transversally to said normal stress direction.

In an embodiment the sheet of piezoelectric material is made of a screen printed layer.

In an embodiment the first, second, third and fourth electrodes are made each of a screen printed layer.

The present disclosure also provides a vehicle brake pad comprising:
a support plate;
a friction pad;
at least a force sensing device; and
an electrical circuit configured to collect signals from said at least a force sensing device;

wherein said shear force sensing device comprises:
a sheet of piezoelectric material having a first and a second main faces parallel to each other identifying a shear stress direction and a normal stress direction orthogonal to said shear stress direction;
at least a first and a second interdigitated electrodes located on said first main face;
at least a third and fourth interdigitated electrodes located on said second main face,

wherein said first and third electrodes are normal stress reading electrodes having digits aligned along said normal stress direction);

wherein said second and fourth electrodes are shear stress reading electrodes having digits aligned along said normal stress direction;

wherein said piezoelectric material comprises, along said shear stress direction, first portions facing said digits of said first and third electrodes interposed with second portions facing said digits of said second and fourth electrodes, said first portions having bulk electric polarization with vector field mostly oriented in alignment with said normal stress direction, said second portions having bulk electric polarization with vector field mostly oriented transversally to said normal stress direction.

The present disclosure further provides a production process of a force sensing device comprising one or more of following steps (e.g., in a time sequence):
screen printing at least a first and a second interdigitated electrodes);
screen printing on said first and second interdigitated electrodes a sheet of piezoelectric material having a first and a second main faces parallel to each other identifying a shear stress direction and a normal stress direction orthogonal to said shear stress direction, said first main face being applied on said first and second reading electrodes;
screen printing on said second main face of said sheet at least a third and a fourth interdigitated electrodes, third electrodes having digits aligned along said normal stress direction and said second and fourth electrodes having digits aligned along said normal direction;
bulk polarizing said sheet of piezoelectric material by a supply of polarization power selectively to said first and third electrodes or respectively to said second and fourth electrodes.

In an embodiment during bulk polarization of said piezoelectric material said second and fourth electrodes or respectively said first and third electrodes are kept at a floating potential.

In an embodiment during bulk polarization of said piezoelectric material said second and fourth electrodes or respectively said first and third electrodes are kept at a fixed and equal potential.

Embodiments of present disclosure additionally provide a production process of a vehicle brake pad comprising one or more of the following steps (e.g., in time sequence):
applying an electrical circuit on a support plate;
screen printing on said electrical circuit at least a first and a second interdigitated electrodes;
screen printing on said first and second interdigitated electrodes a sheet of piezoelectric material having a first and a second main faces parallel to each other identifying a shear stress direction and a normal stress direction orthogonal to said shear stress direction, said first main face being applied on said first and second reading electrodes;
screen printing on said second main face of said sheet at least a third and a fourth interdigitated electrodes, said first and third electrodes having digits aligned along said normal stress direction and said second and fourth electrodes having digits aligned along said normal direction;
applying a friction pad on said support plate;
bulk polarizing said sheet of piezoelectric material by a supply of polarization power selectively to said first and third electrodes or respectively to said second and fourth electrodes.

This way bulk polarization of the piezoelectric material can be made in situ, i.e. on the screen-printed sensing device already integrated in the item to be monitored.

### BRIEF DESCRIPTION OF THE DRAWINGS

Various embodiments are possible, and the accompanying drawings are for illustrative purposes and should in no way be interpreted as limiting the scope of this disclosure.

FIG. 1 schematically shows a vertical cross section of a portion of an embodiment of a vehicle brake pad;

FIG. 2 schematically shows interdigitated electrodes of the force sensor of the vehicle brake pad of FIG. 1; and

FIG. 3 schematically shows a vertical cross section of the force sensing device.

### DETAILED DESCRIPTION

The following detailed description, reference is made to the accompanying drawings, which form a part hereof.

The illustrative embodiments described in the detailed description and drawings are not meant to be limiting.

Other embodiments may be utilized, and other changes may be made, without departing from the spirit or scope of the subject matter presented here.

The aspects of the present disclosure, as generally described herein, and illustrated in the figures, may be arranged, substituted, combined, and designed in a wide variety of different configurations, all of which are explicitly contemplated and made a part of this disclosure.

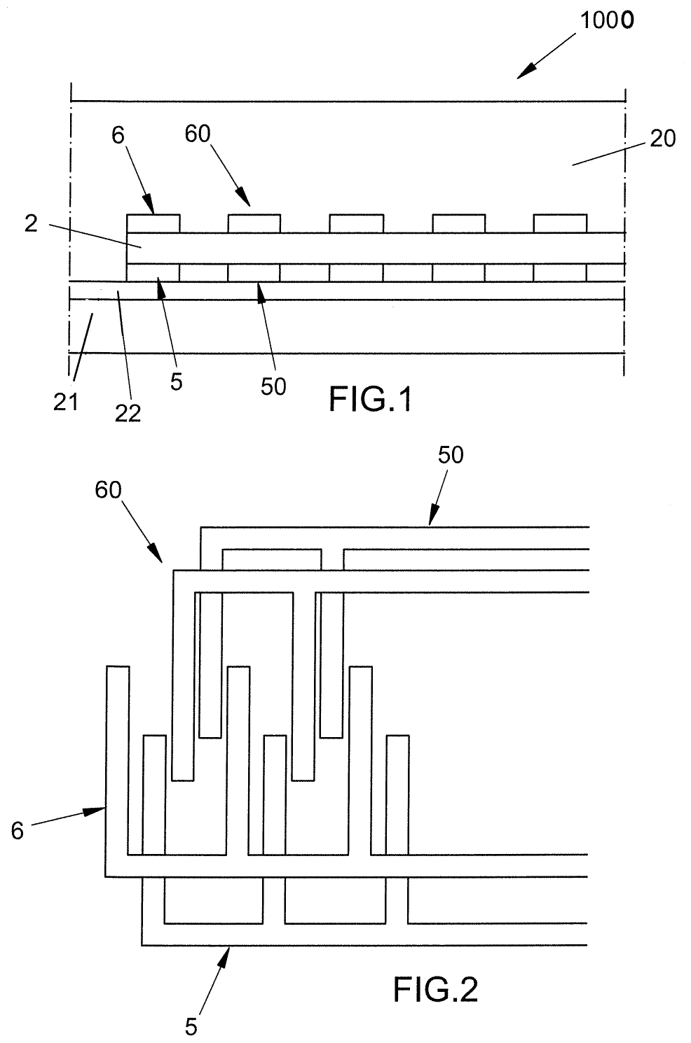

Reference is made now to FIGS. 1-3.

The force sensing device 1 comprises a sheet 2 of piezoelectric material having a first main face 3 and a second main face 4 parallel to each other, parallel to them is identified a shear stress direction S and orthogonal to them is identified a normal stress direction N.

On the first main face 3 of the sheet 2 of piezoelectric material a first and a second interdigitated electrodes 5, 50 is located having digits 5a, 50a.

The first main face 3 of the sheet 2 of piezoelectric material is flat so that the first and the second electrodes 5, 50 are coplanar.

On the second main face 4 of the sheet 2 of piezoelectric material a third and a fourth interdigitated electrodes 6, 60 are located having digits 6a, 60a.

The second main face 4 of the sheet 2 of piezoelectric material is flat so that the third and the fourth electrodes 6, 60 are coplanar.

The first and third electrodes 5 and 6 have digits 5a and 6a aligned to each other along the normal stress direction N.

The second and fourth electrodes 50 and 60 in turn have digits 50a and 60a aligned to each other along the normal stress direction N.

Digits of the first and third electrodes 5, 6 preferably have the same width w so that their homologue longitudinal edges 5a′, 6a′ and 5a″, 6a″ are precisely aligned to each other along the normal stress direction N.

Digits of the second and fourth electrodes 50, 60 preferably have the same width so that their homologue longitudinal edges 50a′, 60a′ and 50a″, 60a″ are precisely aligned to each other along the normal stress direction N.

Preferably, as shown, digits of the first, second, third and fourth electrodes 5, 6, 50 and 60 have the same width w.

Digits of the first and third electrodes 5, 6 preferably have the same length l.

Digits of the second and fourth electrodes 50, 60 preferably have the same length.

Preferably, as shown, digits of the first, second, third and fourth electrodes 5, 6, 50 and 60 have the same length l.

While according to certain embodiments, certain ones of the electrodes 5, 6, 50, 60 can have the same width, length, or both, the present disclosure allows for different electrode geometries and positions on the piezoelectric material, in which the electrodes layout and the electrical potential that the electrodes may differ.

The piezoelectric sheet 2 comprises, along the shear stress direction S, first portions 100 facing digits 5a and 6a of the first and third electrodes 5 and 6 interposed with second portions 101 facing digits 50a and 60a of the second and fourth electrodes 50 and 60.

The first portions 100 have bulk electric polarization with vector field E mostly oriented in alignment with the normal stress direction N, while the second portions 101 have bulk electric polarization with vector field E mostly oriented transversally to the normal stress direction N.

In use the first and third electrodes 5, 6 are normal stress reading electrodes while the second and fourth electrodes 50, 60 are shear stress reading electrodes.

The sheet 2 of piezoelectric material can be made of a screen-printed layer. The piezoelectric material may include synthesized polycrystalline ferroelectric ceramic material, such as barium titanate (BaTiO3) and lead zirconate titanate (PZT). The piezoelectric material of the present disclosure is not limited to synthesized ceramics and may include other types of ferroelectric material. In some embodiments, the screen-printed layer of piezoceramic material may have a thickness within a range of about: 200-300 μm, 100-200 μm or 10-100 μm. In some embodiments, the screen-printed layer of piezoceramic material may have a thickness greater than about 300 μm or less than about 10 μm.

In some embodiments, the electrodes 5, 6, 50, 60 may be formed from a screen-printing layer of metallic material, such as silver, gold, copper, nickel, palladium. In a certain embodiments, the electrodes 5, 6, 50, 60 may be formed from silver ink or paste. In some embodiments, one or more of the electrodes 5, 6, 50, 60 may be partially or fully covered by a protective material, such as a layer of insulation or ceramic glass to electrically and thermally insulate the electrodes and prevent oxidation.

In some embodiments, the electrodes 5, 6, 50, 60 may be screen-printed directly onto a substrate, such as an insulating substrate. The substrate may comprise a protective material.

Each electrode 5, 50, 6, 60 can be made of a screen-printed layer as well, which can be applied to the sheet of piezoelectric material 2.

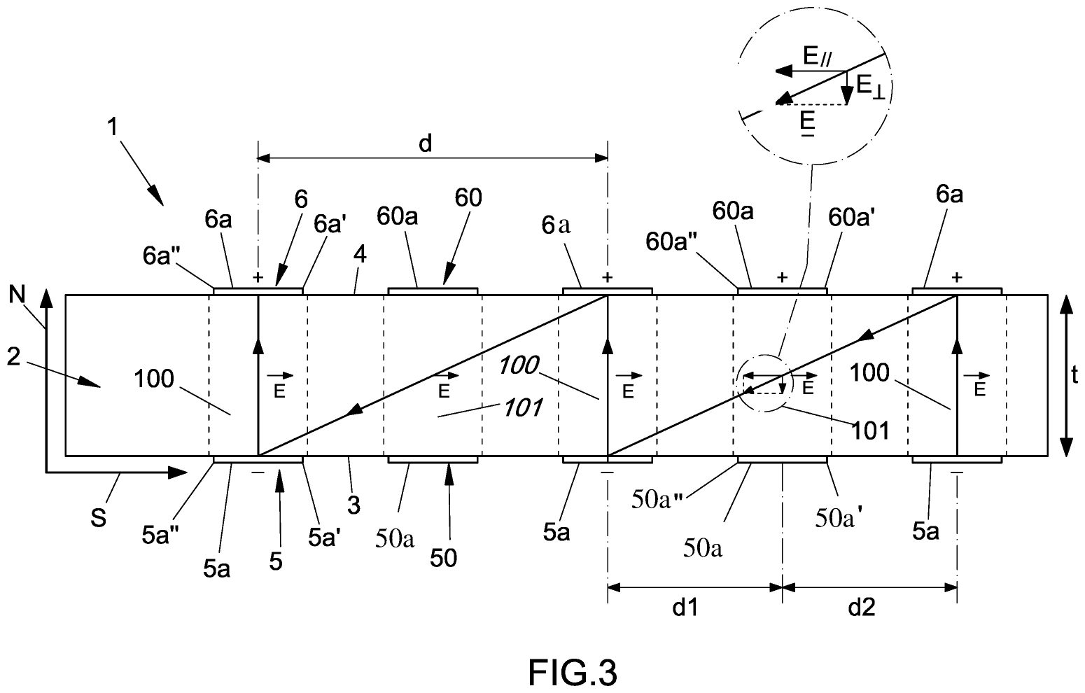

As shown in FIG. 3, each digit 5a of the first electrode 5 can be positioned a distance d apart from the next digit 5a of the first electrode 5 in a direction parallel to the shear stress direction S, e.g., as measured from a center of each digit 5a to a center of the next digit 5a. Similarly, each digit 6a of the third electrode 6 can be positioned a distance d apart from the next digit 6a of the third electrode 6 along the shear stress direction S in a direction parallel to the shear stress direction S, e.g., as measured from a center of each digit 6a to a center of the next digit 6a. In this mannter, where the digits 5a of the first electrode 5 and the digits 6a of the third electrode 6 are aligned in the normal stress direction N, each of the first portions 100 can similarly be spaced apart from one another by a distance d as measured from a center of each first portion 100 to the next first portion 100. In some embodiments, the distance d may be within a range of at least about 3 to about 5 times a thickness t of the piezoelectric material 2. In some embodiments, the distance d may be less than or equal to approximately 3 times the thickness t of the piezoelectric material 2. In some embodiments, the distance d may be greater than or equal to approximately 5 times the thickness t of the piezoelectric material 2.

In some implementations such as the illustrated embodiment, each digit 50a of the second electrode 50 is at a location that is generally centered between digits 5a of the first electrode 5 in the direction parallel to the shear stress direction S. That is, a center of each digit 50a of the second electrode 50 may be positioned substantially at or at a midpoint in between digits 5a of the first electrode 5 in the direction parallel to the shear stress direction S, such that the distances d1, d2 are equal. Similarly, each digit 60a of the fourth electrode 60 is at a location that is generally centered between digits 6a of the third electrode 6 in the direction parallel to the shear stress direction S. That is, a center of each digit 60a of the fourth electrode 60 may be positioned substantially at or at a midpoint in between digits 6a of the third electrode 6 in the direction parallel to the shear stress direction S, such that the distances d1, d2 are equal. In this mannter, where the digits 50a of the second electrode 50 and the digits 60a of the fourth electrode 60 are aligned in the normal stress direction N, each of the second portions 101 can similarly centered between the first portions 100. That is, a center of each second portion may be positioned substantially at or at a midpoint in between the first portions 100, such that the distances d1, d2 are equal.

In some other embodiments, the digits 50a and 60a of the second and fourth electrodes 50, 60 may be positioned opposite each other at a location that is off-centered between the digits 5a, 6a of the first and third electrodes 5, 6 in the direction parallel to the shear stress direction S, such that the distances d1, d2 are different. In such embodiments, the second portions 101 may be positioned at a location that is off-centered between the first portions 100 in the direction parallel to the shear stress direction S, such that the distances d1, d2 are different.

As shown, the digits 50a of the second electrode are positioned distances d1, d2 away from the digits 5a of the first electrode 5. Likewise, the digits 60a of the fourth electrode 60 can be positioned distances d1, d2 away from the digits 6a of the third electrode 6. Where the digits 5a of the first electrode 5 are aligned in the normal stress direction N with the digits 6a of the third electrode 6 and the digits 50a of the second electrode 50 are aligned in the normal stress direction N with the digits 60a of the fourth electrode 60, the second portions 101 can similarly be positioned distances d1, d2 away from the first portions 100. In some embodiments, each of the distances d1, d2 are at least equal to greater than at least twice the thickness t of the piezoelectric material.

Referring to FIG. 1, the force sensing device 1 can be incorporated into a vehicle brake pad 1000.

The force sensing device 1 can be polarized “in situ” after incorporation into the vehicle brake pad 1000.

The brake pad 1000 comprises a support plate 21, a friction pad 20, and an electrical circuit 22 equipped with the force sensor 1 and preferably but not necessarily with other sensors like temperature sensors not shown for real-time detection of signals relating at shear and normal forces and possibly also at temperatures.

The brake pad 1000 can comprise one or more than one force sensor 1 and one or more than one temperature sensor.

The temperature sensors can be thermistors, for example PT1000, PT200 or PT100.

The electrical circuit 22 has electrical terminals arranged in a zone for collecting the signals from said brake pad 1000.

The support plate 21, preferably but not necessarily made of a metal, directly supports the electrical circuit 22.

The friction pad 20 is applied on the side of the support plate 21 where the electrical circuit 22 is present, the electrical circuit 22 is thus incorporated between the support plate 21 and the friction pad 20.

A damping layer can be included, which coats the electrical circuit 22 and is interposed between the friction pad 20 and the support plate 21.

In some embodiments, the brake pad is provided with sensors (Piezoceramic, Piezoelectric, Capacitive, Piezoresistive, Strain Gauges or other force or deformation sensors) and it is composed mostly by four different parts: backplate (metallic support), a sensing layer on the backplate (Electronic Circuit, interconnection media and integrated force and temperature sensors), a damping layer (or Underlayer UL, as optional layer) and a Friction material layer (friction material FM).

The brake pad may include a limited number of sensors in order to limit the number of operations and the power budget of electronics to be suitable for a wireless system for an on-board application.

During use, the brake pad can be capable of transmitting an electrical signal which is proportional to the braking forces applied to said braking element as a result of coming into contact with the element being braked, a braking element that is both easy to be constructed and easily usable.

The force sensor 1 may have, preferably, at least 0.2 mm of thickness and made of piezoceramic material with operating temperature higher than 200° C.

The force sensor 1 allows to measure the actual force applied by the vehicle system to the braking pad.

The electrical circuit 22 on which the sensors are installed is properly electrically insulated.

The electrical circuit 22 has appropriately shaped branches to arrange the sensors in discrete positions on the support plate 21.

The electrical circuit 22 can be a screen-printed circuit.

The brake pad 1000, as mentioned, is provided with appropriate sensors 1 able in working conditions to transmit electrical signals proportional to forces applied to the braking element due to the contact with the element subject to braking.

The brake pad 1000 is applied to the brake caliper of a wheel of a vehicle.

In particular, at least a brake pad 1000 is included for each braking caliper, and therefore for example a total of at least four brake pad are on-board the vehicle.

The production process of the force sensing device 1 comprises in a time sequence the step of screen printing the first and second interdigitated electrodes 5, 50, then screen printing the piezoelectric sheet 2 on the first and second interdigitated electrodes 5, 50, with the first main face 3 facing the first and second interdigitated electrodes 5, 50, then screen printing on the second main face 4 of the piezoelectric sheet 2 the third and fourth interdigitated electrodes 6, 60, then bulk polarizing the piezoelectric sheet 2 by a supply of a polarization power selectively to the first and third electrodes 5, 6. This causes the portions 100 to be aligned with the normal stress direction due to the field between electrodes 5 and 6. Does this also cause the oblique electric field vectors shown in FIG. 3, between 6a and 5a.

In FIG. 3, E represents the electric, E⊥ represents the component of the electric vector E normal to the shear stress direction S and E∥ represents the component of the electric vector E parallel to the shear stress direction S.

Advantageously in each portion 101 between each pair of aligned digits 50a, 60a the vector E is most tangentially oriented to the shear stress direction S, that is to say an E∥ component of the electric vector E is much larger than an E⊥ component of the electric vector E. In several embodiments, the magnitude of the E⊥ component is substantially zero and/or the magnitude of the E∥ component may be within a range of at least about 10 to about 100 times greater than the magnitude of the E⊥ component. In some embodiments, the magnitude of the ED component may at least approximately 100 times greater than the magnitude of the E⊥ component. In some embodiments, the magnitude of the E∥ component may be less than or equal to about 10 times greater than the magnitude of the E⊥ component.

In FIG. 3 signs “+” and “−” refer to voltage polarity applied to the first and third electrodes 5 and 6 during the polarization step.

During bulk polarization of the piezoelectric sheet 2 the second and fourth electrodes 50, 60 are preferably kept at a floating potential.

Alternatively, during bulk polarization of the piezoelectric sheet 2 the second and fourth electrodes 50, 60 can be kept at a fixed and equal potential.

The production process of the vehicle brake pad 1000 comprises in time sequence a step of applying the electrical circuit 22 on the support plate 21, then the step of screen printing on the electrical circuit 22 the first and second interdigitated electrodes 5, 50, then the step of screen printing the piezoelectric sheet 2 on the first and second interdigitated electrodes 5, 50, then the step of screen printing on of the third and fourth interdigitated electrodes 6, 60 on the second main face 4 of the piezoelectric sheet 2, then the step of applying the friction pad 20 on the support plate 21, then the step of bulk polarizing the piezoelectric sheet 2 as seen above.

During the reading phase, all the four electrodes 5, 6, 50, 60 are used to collect the signal produced by the deformation of the piezo material 2.

In more detail the first and third electrodes 5, 6 act as normal stress reading electrodes while the second and fourth electrodes 50, 60 act as shear stress reading electrodes.

The signal produced by the deformation of the piezoelectric sheet 2 can be collected in the electrical reading circuit as a voltage signal measured through a resistor.

To get the normal stress signal, current from the first couple of reading electrodes 5, 6 is collected by connecting to a reference potential (ground potential) one of those electrodes 5 and 6 and letting the current pass through a first measuring resistor connecting the first couple of reading electrodes 5, 6.

To get the shear stress signal, current from the second couple of reading electrodes couples 50, 60 is collected by connecting to a reference potential (ground potential) one of those electrodes 50 and 60 and letting the current pass through a second measuring resistor connecting the second couple of reading electrodes 50, 60.

It is now clear the both the first couple 5, 6 and respectively the second couple 50, 60 of electrodes are used to read normal stress and respectively shear stress during the reading phase, while only one couple between the first couple 5, 6 and the second couple 50, 60 of electrodes is used to polarize the piezoelectric sheet 2.

The force sensing device, the brake pad and production process thereof thus conceived are susceptible of numerous modifications and variants, all falling within the scope of the inventive concept; moreover, all the details as well as the dimensions may be replaced with other technically equivalent ones, according to need and the state of the art.

Generally, the voltage required to polarize the piezoelectric material of the present disclosure may be several orders of magnitude less than previously known manufacturing methods. This may be due to the relatively small thickness of the piezoelectric material, which is formed by screen-printing. In some embodiments, the voltage applied to the electrodes 5, 6 during the polarization phase may be between about 2 to about 3 kV/mm distance d in the shear stress direction S. In some embodiments, the voltage applied to the electrodes 5 and 6 during the polarization phase may be less than or equal to approximately 1 kV/mm, between about 1 to about 2 kV/mm, or greater than or equal to about 3 kV/mm. The voltage applied to the polarizing lectrodes 5 and 6 to polarize the piezoelectric material may vary according to, for example, the size, geometry and positions of the electrodes 5, 6, 50, 60 the type or thickness of piezoelectric material, etc.

The ability to polarize the piezoelectric material in situ is in contrast to manufacturing methods in which the piezoelectric material is polarized prior to or during the manufacturing process of the sensor. In situ polarizing allows the piezoelectric material of the present disclosure to be polarized after the sensor has been manufactured and installed into an application. In situ polarizing of the piezoelectric material is possible due, in part, to the relatively small thickness of the screen-printed piezoelectric material which generally requires low voltage to be polarized. As a result, a power source provided by the application may be sufficient to polarize the sensor in situ or, in other words, while the sensor is installed in the application. Therefore, in contrast to other manufacturing methods, the piezoelectric sensor of the present disclosure provides flexibility in terms of when the piezoelectric material may be polarized.

In certain implementations, the piezoelectric material of the present disclosure may be polarized during the manufacturing process of the sensor itself For example, the piezoelectric material may be polarized immediately after the polarizing electrodes (e.g., electrodes 5 and 6) are screen-printed onto the sheet 2 of piezoelectric material.

In some embodiments and in contrast to manufacturing methods in which the piezoelectric material is polarized during the manufacturing process of the sensor, the piezoelectric material of the present disclosure may be re-polarized while installed in the application, after already being initially polarized.

The present disclosure also relates to smart brake pads. A smart brake pad is a sensorized brake pad configured (e.g., with appropriate software and hardware system architecture and some algorithms) to measure one or more parameters, such as the brake pad temperature and/or static and dynamic quantities including normal and shear forces applied during braking.

Although certain sensing devices, systems, and methods of manufacture have been disclosed in the context of certain example embodiments, it will be understood by those skilled in the art that the scope of this disclosure extends beyond the specifically disclosed embodiments to other alternative embodiments and/or uses of the embodiments and certain modifications and equivalents thereof Use with any structure is expressly within the scope of this invention. Various features and aspects of the disclosed embodiments can be combined with or substituted for one another in order to form varying modes of the assembly. The scope of this disclosure should not be limited by the particular disclosed embodiments described herein.

Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as any subcombination or variation of any subcombination.

Terms of orientation used herein, such as “top,” “bottom,” “proximal,” “distal,” “longitudinal,” “lateral,” and “end” are used in the context of the illustrated embodiment. However, the present disclosure should not be limited to the illustrated orientation. Indeed, other orientations are possible and are within the scope of this disclosure. Terms relating to circular shapes as used herein, such as diameter or radius, should be understood not to require perfect circular structures, but rather should be applied to any suitable structure with a cross-sectional region that can be measured from side-to-side. Terms relating to shapes generally, such as “circular” or “cylindrical” or “semi-circular” or “semi-cylindrical” or any related or similar terms, are not required to conform strictly to the mathematical definitions of circles or cylinders or other structures, but can encompass structures that are reasonably close approximations.

Conditional language, such as “can,” “could,” “might,” or “may,” unless specifically stated otherwise, or otherwise understood within the context as used, is generally intended to convey that certain embodiments include or do not include, certain features, elements, and/or steps. Thus, such conditional language is not generally intended to imply that features, elements, and/or steps are in any way required for one or more embodiments.

Conjunctive language, such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

The terms “approximately,” “about,” and “substantially” as used herein represent an amount close to the stated amount that still performs a desired function or achieves a desired result. For example, in some embodiments, as the context may dictate, the terms “approximately”, “about”, and “substantially” may refer to an amount that is within less than or equal to 10% of the stated amount. The term “generally” as used herein represents a value, amount, or characteristic that predominantly includes or tends toward a particular value, amount, or characteristic. As an example, in certain embodiments, as the context may dictate, the term “generally parallel” can refer to something that departs from exactly parallel by less than or equal to 20 degrees.

Some embodiments have been described in connection with the accompanying drawings. The figures are to scale, but such scale should not be interpreted as limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components can be added, removed, and/or rearranged. Further, the disclosure herein of any particular feature, aspect, method, property, characteristic, quality, attribute, element, or the like in connection with various embodiments can be used in all other embodiments set forth herein. Additionally, it will be recognized that any methods described herein may be practiced using any device suitable for performing the recited steps.

Various illustrative embodiments of shear force sensing devices, systems, and methods of manufacture have been disclosed. Although the devices, systems, and methods have been disclosed in the context of those embodiments, this disclosure extends beyond the specifically disclosed embodiments to other alternative embodiments and/or other uses of the embodiments, as well as to certain modifications and equivalents thereof This disclosure expressly contemplates that various features and aspects of the disclosed embodiments can be combined with, or substituted for, one another. Accordingly, the scope of this disclosure should not be limited by the particular disclosed embodiments described above, but should be determined only by a fair reading of the claims that follow as well as their full scope of equivalents.

1. A force sensing device (1) comprising:
a piezoelectric material (2) comprising a first face (3) and a second face (4) opposite the first face (3), the first and second faces (3, 4) extending parallel to each other in a shear stress direction, where a normal stress direction is orthogonal to said shear stress direction;
a first interdigitated electrode (5) positioned on said first face (3) and a second interdigitated electrode (50) positioned on said first face (3);
a third interdigitated electrode (6) positioned on said second face (4) and a fourth interdigitated electrode (60) positioned on said second face (4);
wherein said first and third interdigitated electrodes (5, 6) are normal stress reading electrodes and one or more digits of the first interdigitated electrode (5) are aligned with one or more corresponding digits of the third interdigitated electrode (6) along said normal stress direction;
wherein said second and fourth interdigitated electrodes (50, 60) are shear stress reading electrodes and one or more digits of the second interdigitated electrode (50) are aligned with one or more corresponding digits of the fourth interdigitated electrode (60) along said normal stress direction;
wherein said piezoelectric material comprises one or more first portions (100) and one or more second portions (101) interposed with the one or more first portions (100) along said shear stress direction, the one or more first portions (100) extend along the normal stress direction between the one or more digits of said first interdigitated electrode (5) and the corresponding digits of the third interdigitated electrode (6), the one or more second portions (101) extend along the normal stress direction between the one or more digits of said second interdigitated electrode (50) and the corresponding digits of the fourth interdigitated electrode (60), said one or more first portions (100) have a bulk electric polarization vector field more closely aligned with said normal stress direction (N) than with said shear stress direction, and said second portions (101) have a bulk electric polarization vector field more closely aligned with said shear stress direction than with said normal stress direction.

2. The force sensing device according to claim 1, wherein said piezoelectric material comprises a screen-printed layer.

3. The force sensing device according to claim 1, wherein said first, second, third and fourth interdigitated electrodes each comprise a screen printed layer.

4. The force sensing device according to claim 1, wherein:
said one or more first portions (100) are substantially aligned with said normal stress direction; and
said one or more second portions (101) are aligned obliquely with respect to said shear stress direction.

5. A vehicle brake pad (1000) comprising:
a support plate (21);
a friction pad (20);
at least one force sensing device; and
an electrical circuit (22) configured to collect signals from said at least one force sensing device;
wherein said at least one force sensing device comprises:
a piezoelectric material comprising a first face (3) and a second face (4) opposite the first face (3), the first and second faces (3, 4) extending parallel to each other in a shear stress direction, where a normal stress direction is orthogonal to said shear stress direction;
a first interdigitated electrode (5) positioned on said first face (3) and a second interdigitated electrode (50) positioned on said first face (3);
a third interdigitated electrode (6) positioned on said second face (4) and a fourth interdigitated electrode (60) positioned on said second face (4);
wherein said first and third interdigitated electrodes (5, 6) are normal stress reading electrodes and one or more digits of the first interdigitated electrode (5) are aligned with one or more corresponding digits of the third interdigitated electrode (6) along said normal stress direction; and
wherein said second and fourth interdigitated electrodes (50, 60) are shear stress reading electrodes and one or more digits of the second interdigitated electrode (50) are aligned with one or more corresponding digits of the fourth interdigitated electrode (60) along said normal stress direction,
wherein, along said shear stress direction, said second and fourth interdigitated electrodes (50, 60) are positioned between the first and third interdigitated electrodes (5, 6).

6. The vehicle brake pad according to claim 5, wherein said piezoelectric material comprises one or more first portions (100) and one or more second portions (101), the one or more first portions (100) extend along the normal stress direction between the one or more digits of said first interdigitated electrode (5) and the one or more corresponding digits of the third interdigitated electrode (6), the one or more second portions (101) extend along the normal stress direction between the one or more digits of said second interdigitated electrode (50) and the one or more corresponding digits of the fourth interdigitated electrode (60), said one or more first portions (100) have a bulk electric polarization vector field oriented to allow for force detection in the normal stress direction, and said second portions (101) have a bulk electric polarization vector field oriented to allow for force detection in the shear stress direction.

7. The vehicle brake pad according to claim 6 wherein said first portions (100) have a bulk electric polarization vector field substantially aligned with the normal stress force direction and said second portions (101) have a bulk electric polarization vector field aligned obliquely with the shear stress force direction.

8. A method of manufacturing a vehicle brake pad, the method comprising:
mating an electrical circuit (22) on a support plate (21);
forming a piezoelectric assembly; and
mating the piezoelectric assembly with said electrical circuit (22),
wherein said forming the piezoelectric assembly comprises:
mating a first interdigitated electrode (5) to a first face (3) of a piezoelectric material, wherein the piezoelectric material comprises the first face (3) and a second face (4) opposite the first face (3), the first and second faces (3, 4) extending parallel to each other in a shear stress direction, where a normal stress direction is orthogonal to said shear stress direction;
mating a second interdigitated electrode (50) to said first face (3);
mating a third interdigitated electrode (6) to said second face (4), wherein one or more digits of the first interdigitated electrode (5) are aligned with one or more corresponding digits of the third interdigitated electrode (6) along said normal stress direction;
mating a fourth interdigitated electrode (60) to said second face (4), wherein one or more digits of the second interdigitated electrode (50) are aligned with one or more corresponding digits of the fourth interdigitated electrode (60) along said normal stress direction; and
supplying electric power to said first and third interdigitated electrodes (5, 6) to polarize the piezoelectric assembly by generating a first vector field orientation in first portions (100) of the piezoelectric material extending between the one or more digits of the first interdigitated electrode (5) and the one or more corresponding digits of the third interdigitated electrode (6), and generating a second vector field orientation in second portions (101) of the piezoelectric material extending between the one or more digits of the second interdigitated electrode (50) and the one or more corresponding digits of the fourth interdigitated electrode (60),
wherein the first vector field orientation allows for force detection in the normal stress direction and the second vector field orientation allows for force detection in the shear stress direction.

9. The method according to claim 8 wherein the first vector field orientation is aligned more closely with the normal stress direction than the shear stress direction and the second vector field orientation is aligned more closely with the shear stress direction than the normal stress direction.

10. The method according to claim 8 wherein the first vector field orientation is substantially aligned with the normal stress direction and the second vector field orientation is aligned obliquely to the shear stress direction.

11. The method according to claim 8 wherein the steps of mating a third interdigitated electrode (6) to said second face (4) and mating a fourth interdigitated electrode (60) to said second face (4) comprise screen-printing the third and fourth interdigitated electrodes (6, 60) on the second face (4) of the piezoelectric material.

12. A method of manufacturing a force sensing device, the method comprising:
forming a piezoelectric assembly;
mating the piezoelectric assembly with said electrical circuit,
wherein said forming the piezoelectric assembly comprises:
mating a first interdigitated electrode (5) to a first face (3) of a piezoelectric material,
wherein the piezoelectric material comprises the first face (3) and a second face (4) opposite the first face (3), the first and second faces (3, 4) extending parallel to each other in a shear stress direction, where a normal stress direction is orthogonal to said shear stress direction;
mating a second interdigitated electrode (50) to said first face (3);
mating a third interdigitated electrode (6) to said second face (4), wherein one or more digits of the first interdigitated electrode (5) are aligned with one or more corresponding digits of the third interdigitated electrode (6) along said normal stress direction;
mating a fourth interdigitated electrode (60) to said second face (4), wherein one or more digits of the second interdigitated electrode (50) are aligned with one or more corresponding digits of the fourth interdigitated electrode (60) along said normal stress direction; and
supplying electric power to said first and third interdigitated electrodes (5, 6) to polarize the piezoelectric assembly by generating a first vector field orientation in first portions (100) of the piezoelectric material extending between the one or more digits of the first interdigitated electrode (5) and the one or more corresponding digits of the third interdigitated electrode (6), and generating a second vector field orientation in second portions (101) of the piezoelectric material extending between the one or more digits of the second interdigitated electrode (50) and the one or more corresponding digits of the fourth interdigitated electrode (60),
wherein the first vector field orientation allows for force detection in the normal stress direction and the second vector field orientation allows for force detection in the shear stress direction.

13. The method according to claim 12 wherein the first vector field orientation is aligned more closely with the normal stress direction than the shear stress direction and the second vector field orientation is aligned more closely with the shear stress direction than the normal stress direction.

14. The method according to claim 12 wherein the first vector field orientation is substantially aligned with the normal stress direction and the second vector field orientation is aligned obliquely to the shear stress direction.
